(19) United States
(12) Patent Application Publication
(10) Pub. No.: US 2014/0141577 A1
(43) Pub. Date: May 22, 2014

(54) METHOD OF MANUFACTURING THIN FILM TRANSISTOR ARRAY PANEL

(71) Applicant: SAMSUNG DISPLAY CO., LTD., Yongin-City (KR)

(72) Inventor: Won-Mo PARK, Yongin-City (KR)

(73) Assignee: SAMSUNG DISPLAY CO., LTD., Yongin-City (KR)

(21) Appl. No.: 14/056,233

(22) Filed: Oct. 17, 2013

(30) Foreign Application Priority Data
Nov. 20, 2012 (KR) 10-2012-0131984

(51) Int. Cl. H01L 29/66

(52) U.S. Cl. CPC H01L 29/66742
USPC 438/158

(57) ABSTRACT

A method of manufacturing a thin film transistor array panel includes forming a semiconductor on a substrate, forming a gate insulating layer on the semiconductor, forming a sacrificial layer including an opening on the gate insulating layer, forming a copper layer on the sacrificial layer, the copper layer filling the opening, forming a gate wiring by polishing the copper layer by chemical mechanical polishing until the sacrificial layer is exposed, removing the sacrificial layer, forming a source region and a drain region by doping conductive impurities on the semiconductor by using the gate wiring as a mask, forming a first interlayer insulating layer covering the gate wiring, and forming a source electrode and a drain electrode connected to the source region and the drain region, respectively, on the first interlayer insulating layer.

### RELATED APPLICATIONS

This application claims priority to and the benefit of Korean Patent Application No. 10-2012-0131984 filed in the Korean Intellectual Property Office on Nov. 20, 2012, the entire contents of which are incorporated herein by reference.

### BACKGROUND

1. Field

Embodiments relate to a method of manufacturing a thin film transistor array panel.

2. Description of the Related Art

In general, a thin film transistor (TFT) array panel is used as a circuit board for independently driving each pixel in a liquid crystal display (LCD), an organic electro luminescence (EL) display, and the like. The thin film transistor is a switching element for transmitting or blocking a data voltage transmitted to a pixel electrode according to a gate signal.

The above information disclosed in this Background section is only for enhancement of understanding of the background of the described technology and therefore it may contain information that does not form the prior art that is already known in this country to a person of ordinary skill in the art.

### SUMMARY

Embodiments are directed to a method of manufacturing a thin film transistor array panel, the method including forming a semiconductor on a substrate, forming a gate insulating layer on the semiconductor, forming a sacrificial layer including an opening on the gate insulating layer, forming a copper layer on the sacrificial layer, the copper layer filling the opening, forming a gate wiring by polishing the copper layer by chemical mechanical polishing until the sacrificial layer is exposed, removing the sacrificial layer, forming a source region and a drain region by doping conductive impurities on the semiconductor by using the gate wiring as a mask, forming a first interlayer insulating layer covering the gate wiring, and forming a source electrode and a drain electrode connected to the source region and the drain region, respectively, on the first interlayer insulating layer.

The sacrificial layer may be formed of silicon nitride or tungsten.

The sacrificial layer may be formed to a thickness of about 3,500 Å to about 4,500 Å.

Embodiments are also directed to a method of manufacturing a thin film transistor array panel, the method including forming a semiconductor on a substrate, forming a gate insulating layer on the semiconductor, forming an etch stop layer on the gate insulating layer, forming a sacrificial layer including an opening on the etch stop layer, forming a copper layer on the sacrificial layer, the copper layer filling the opening, forming an upper layer of a gate electrode by polishing the copper layer by chemical mechanical polishing until the sacrificial layer is exposed, removing the sacrificial layer, forming a lower layer of the gate electrode by removing the exposed etch stop layer, forming a source region and a drain region by doping conductive impurities on the semiconductor by using the gate electrode as a mask, forming a first interlayer insulating layer covering the upper and lower gate electrode layers, and forming a source electrode and a drain electrode connected to the source region and the drain region, respectively, on the first interlayer insulating layer.

The sacrificial layer may be formed of silicon nitride.

The sacrificial layer may be formed to a thickness of about 3,500 Å to about 4,500 Å.

The etch stop layer may be formed of tungsten.

The etch stop layer may be formed to a thickness of about 100 Å to about 500 Å.

### BRIEF DESCRIPTION OF THE DRAWINGS

Features will become apparent to those of skill in the art by describing in detail exemplary embodiments with reference to the attached drawings in which:

FIG. 1 is a circuit diagram illustrating a pixel circuit included in an organic light emitting diode display according to an example embodiment.

FIG. 2 is a layout view of one pixel of the organic light emitting diode display of FIG. 1.

FIG. 3 is a cross-sectional view taken along line III-III of FIG. 2.

FIGS. 4 to 10 are views illustrating a method of manufacturing an organic light emitting diode display according to an example embodiment according to a process order.

FIG. 11 is a cross-sectional view of an organic light emitting diode display according to another example embodiment, and is a cross-sectional view taken along line III-III of FIG. 2.

FIGS. 12 to 15 are cross-sectional views illustrating a method of manufacturing the organic light emitting diode display according to another example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereafter, an organic light emitting diode display according to an example embodiment will be described in detail with reference to the drawings.

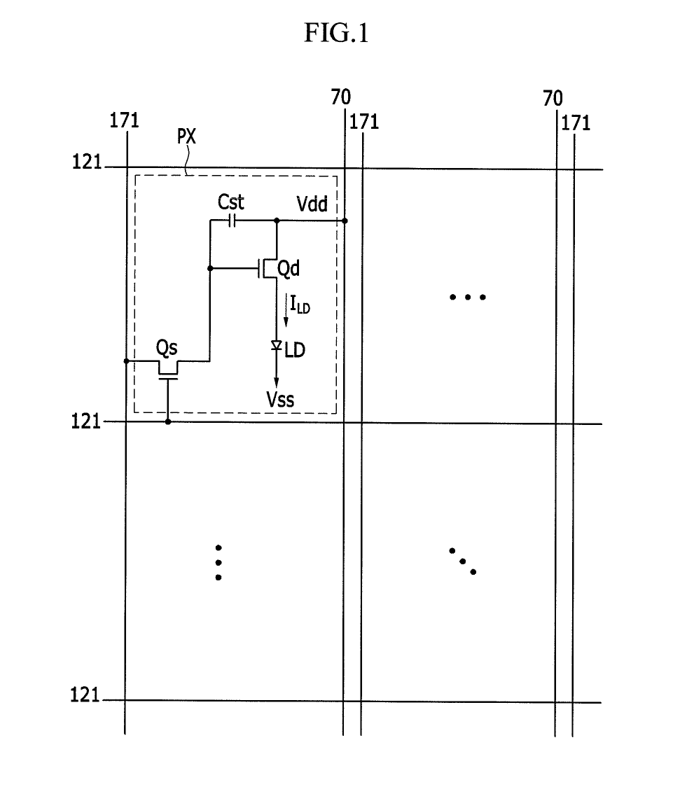

FIG. 1 is a circuit diagram illustrating a pixel circuit included in an organic light emitting diode display according to an example embodiment.

In the example embodiment illustrated in FIG. 1, the organic light emitting diode display according to the present example embodiment includes a plurality of signal lines 121, 171, and 172, and a plurality of pixels PX connected to the signal lines 121, 171, and 172 and approximately arranged in a matrix.

The signal lines include a plurality of gate lines 121 for transmitting a gate signal (or a scan signal), a plurality of data lines 171 for transmitting a data signal, and a plurality of driving voltage lines 172 for transmitting a driving voltage Vdd. Gate lines 121 approximately extend in a row direction and are substantially parallel to each other, and portions in a vertical direction of the data lines 171 and the driving voltage lines 172 approximately extend in a column direction and are substantially parallel to each other.

Each pixel (PX) includes a switching thin film transistor Qs, a driving thin film transistor Qd, a storage capacitor Cst, and an organic light emitting diode (OLED) LD.

The switching thin film transistor Qs includes a control terminal, an input terminal, and an output terminal, and the control terminal is connected to the gate line 121, the input terminal is connected to the data line 171, and the output terminal is connected to the driving thin film transistor Qd. The switching thin film transistor Qs transmits a data signal applied to the data line 171 to the driving thin film transistor Qd in response to a scan signal applied to the gate line 121.

The driving thin film transistor Qd also includes a control terminal, an input terminal, and an output terminal, and the control terminal is connected to the switching thin film transistor Qs, the input terminal is connected to the driving voltage line 172, and the output terminal is connected to the organic light emitting diode LD. The driving thin film transistor Qd enables output current ILD, of which a size is changed according to a voltage applied between the control terminal and the output terminal, to flow.

The capacitor Cst is connected between the control terminal and the input terminal of the driving thin film transistor Qd. The capacitor Cst charges a data signal applied to the control terminal of the driving thin film transistor Qd, and maintains the charged signal after the switching thin film transistor Qs is turned off.

The organic light emitting diode LD includes an anode connected to the output terminal of the driving thin film transistor Qd and a cathode connected to a common voltage Vss. The organic light emitting diode LD displays an image by emitting light while changing intensity of the light according to the output current ILD of the driving thin film transistor Qd.

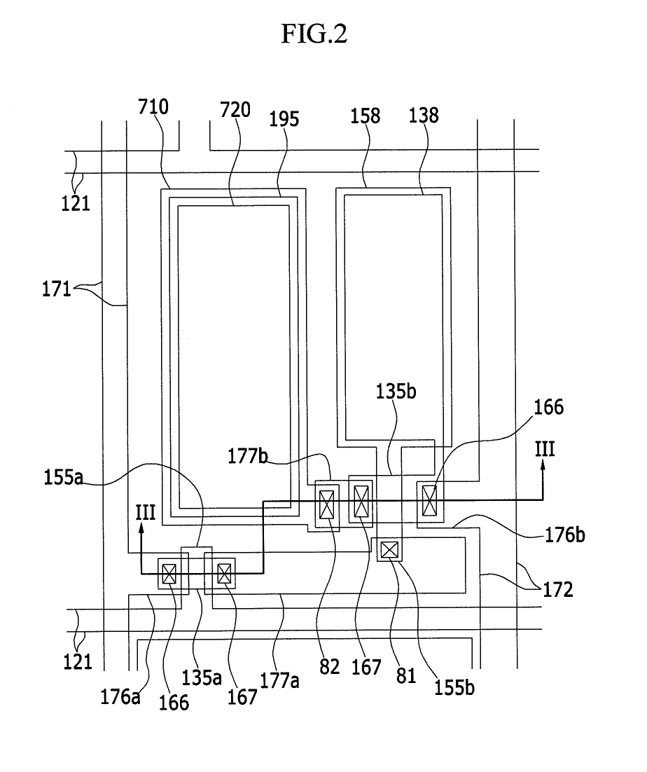

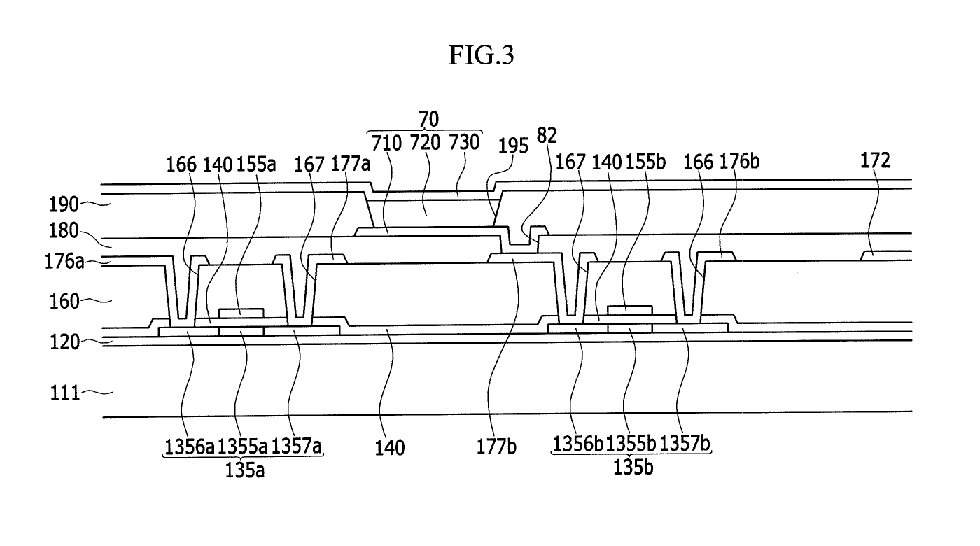

Hereinafter, the organic light emitting diode display according to the example embodiment will be described in detail with reference to FIGS. 2 and 3.

FIG. 2 is a layout view of one pixel of the organic light emitting diode display of FIG. 1, and FIG. 3 is a cross-sectional view taken along line of FIG. 2.

In the example embodiment illustrated in FIGS. 2 and 3, a buffer layer 120 is formed on a substrate 111.

The substrate 111 may be a transparent insulating substrate formed of, e.g., glass, quartz, ceramic, or plastic, and the substrate 111 may be a metallic substrate formed of, e.g., stainless steel or the like.

The buffer layer 120 may be formed as a single layer formed of silicon nitride (SiNx) or in a dual layer structure in which silicon nitride (SiNx) and silicon oxide (SiO₂) are stacked. The buffer layer 120 may simultaneously serve to prevent undesirable elements, such as impurities or water, from penetrating, and planarize a surface.

A first semiconductor 135a, a second semiconductor 135b formed of, e.g., polycrystalline silicon, and a first capacitor electrode 138 are formed on the buffer layer 120.

The first semiconductor 135a and the second semiconductor 135b are divided into channel regions 1355a and 1355b, and source regions 1356a and 1356b and drain regions 1357a and 1357b formed at both sides of the channel regions 1355a and 1355b, respectively. The channel regions 1355a and 1355b of first semiconductor 135a and the second semiconductor 135b may be polycrystalline silicon intrinsic semiconductors, on which an impurity is not doped. The source regions 1356a and 1356b and the drain regions 1357a and 1357b of the first semiconductor 135a and the second semiconductor 135b may be polycrystalline silicon impurity semiconductors, on which a conductive impurity is doped.

The impurity doped on the source regions 1356a and 1356b, the drain regions 1357a and 1357b, and the first capacitor electrode 138 may be any one of a p-type impurity and an n-type impurity.

A gate insulating layer 140 is formed on the first semiconductor 135a, the second semiconductor 135b, and the first capacitor electrode 138. The gate insulating layer 140 may be a single layer or a multilayer including, e.g., one or more of tetra ethyl ortho silicate (TEOS), silicon nitride, silicon oxide, etc.

The gate line 121 extends in a horizontal direction to transmit a gate signal, and includes a first gate electrode 155a protruding from the gate line 121 toward the first semiconductor 135a.

The first gate electrode 155a and the second gate electrode 155b overlap the channel regions 1355a and 1355b, respectively, and a second capacitor electrode 158 overlaps the first capacitor electrode 138.

The second capacitor electrode 158, the gate line 121, and the second gate electrode 155b may be formed of copper (Cu) or a copper alloy.

The first capacitor electrode 138 and the second capacitor electrode 158 form a capacitor 80 by using the gate insulating layer 150 as a dielectric. The capacitor 80 may form an MIM-type capacitor with separate metal patterns overlapping with the second capacitor electrode 158 and the insulating layer interposed therebetween, instead of the first capacitor electrode 138. For example, the capacitor 80 may be formed by using the second capacitor electrode 158 and a first interlayer insulating layer or a second interlayer insulating layer to be described below as a dielectric, and overlapping the metal patterns formed on the same layer as that of the drain electrode or the first electrode.

A first interlayer insulating layer 160 is formed on the gate line 121, the second gate electrode 155b, and the second capacitor electrode 158.

The first interlayer insulating layer 160 may be formed of a single layer or a multiple layer formed of, e.g., tetra ethyl ortho silicate (TEOS), silicon nitride, or silicon oxide, similar to the gate insulating layer 140.

The first interlayer insulating layer 160 and the gate insulating layer 140 include source contact holes 166 and drain contact holes 167 through which the source regions 1356a and 1356b and the drain regions 1357a and 1357b are exposed, respectively.

The data lines 171 including a first source electrode 176a, the driving voltage lines 172 including a second source electrode 176b, and a first drain electrode 177a, and a second drain electrode 177b are formed on the first interlayer insulating layer 160.

The data line 171 transmits a data signal and extends in a direction crossing the gate line 121, and the driving voltage line 172 transmits a predetermined voltage and extends in the same direction as that of the data line 171 while being separated from the data line 171.

The first source electrode 176a protrudes toward the first semiconductor 135a from the data line 171, and the second source electrode 176b protrudes toward the second semiconductor 135b from the driving voltage line 172. The first source electrode 176a and the second source electrode 176b are connected to the source regions 1356a and 1356b through the source contact holes 166, respectively.

The first drain electrode 177a faces the first source electrode 176a and is connected with the drain region 1357a through the contact hole 167. Further, the second drain electrode 177b faces the second source electrode 176b and is connected with the drain region 1357b through the contact hole 167.

The first drain electrode 177a extends along the gate line, and is electrically connected with the second gate electrode 158b through the contact hole 81.

The data line 171, the driving voltage line 172, the first drain electrode 177a, and the second drain electrode 177b may be formed as a single layer or a multilayer formed of a low-resistance material or a metal, such as Al, Ti, Mo, Cu, Ni, or an alloy thereof. For example, the data line 171, the driving voltage line 172, the first drain electrode 177a, and the second drain electrode 177b may be formed as a triple layer formed of Ti/Cu/Ti, Ti/Ag/Ti, or Mo/Al/Mo.

The first gate electrode 155a, the first source electrode 176a, and the first drain electrode 177a form the first thin film transistor (TFT) Qa together with the first semiconductor 135a, and the second gate electrode 155b, the second source electrode 176b, and the second drain electrode 177b forms the second thin film transistor Qb together with the second semiconductor 135b.

Channels of the first thin film transistor Qa and the second thin film transistor Qb are formed at the first semiconductor 135a between the first source electrode 176a and the first drain electrode 177a, and the second semiconductor 135b between the second source electrode 176b and the second drain electrode 177b, respectively.

A second interlayer insulating layer 180 is formed on the data line 171, the driving voltage line 172, the first drain electrode 177a, and the second drain electrode 177b.

The second interlayer insulating layer 180 may be formed of a single layer or a multilayer formed of, e.g., tetra ethyl ortho silicate (TEOS), silicon nitride, or silicon oxide, similar to the first interlayer insulating layer, and may be formed of an organic material having a low dielectric constant.

The second interlayer insulating layer 180 includes a contact hole 82 through which the second drain electrode 177b is exposed.

A first electrode 710 is formed on the second interlayer insulating layer 180. The first electrode 710 may be an anode electrode of the organic light emitting device of FIG. 1. In the present example embodiment, an interlayer insulating layer is formed between the first electrode 710 and the second drain electrode 177b, but the first electrode 710 may be formed on the same layer as that of the second drain electrode 177b, and be integrally formed with the second drain electrode 177b.

The pixel defining layer 190 is formed on the first electrode 710.

A pixel defining layer 190 includes an opening 195 through which the first electrode 710 is exposed. The pixel defining layer 190 may be formed of resin, such as polyacryl-based (polyacrylates) or polyimide-based (polyimides) resin and a silica-based inorganic material.

An organic emission layer 720 is formed on the opening 195 of the pixel defining layer 190.

The organic emission layer 720 may be formed as a multilayer including an emission layer and one or more of a hole-injection layer (HIL), a hole-transporting layer (HTL), an electron-transporting layer (ETL), and an electron-injection layer (EIL). When the organic emission layer 720 includes all of them, the hole-injection layer is formed on the pixel electrode 710, that is, the anode electrode, and the hole-transporting layer, the emission layer, the electron-transporting layer, and the electro-injection layer are sequentially stacked on the hole-injection layer.

A second electrode 730 is formed on the pixel defining layer 190 and the organic emission layer 720.

The second electrode 730 is a cathode electrode of the organic light emitting diode. Accordingly, the first electrode 710, the organic emission layer 720, and the second electrode 730 form an organic light emitting diode 70.

The organic light emitting diode display may have any one structure among a top display type, a rear display type, and a both-side display type according to a direction in which the organic light emitting diode 70 emits light.

In a case of the top display type, the first electrode 710 is formed as a reflective layer, and the second electrode 730 is formed as a semi-transmissive layer or a transmissive layer. In the meantime, in a case of the rear display type, the first electrode 710 is formed as a semi-transmissive layer, and the second electrode 730 is formed as a reflective layer. Further, in a case of the both-side display type, the first electrode 710 and the second electrode 730 are formed as a transparent layer or a semi-transmissive layer.

The reflective layer and the semi-transmissive layer may be made of at least one metal among magnesium (Mg), silver (Ag), gold (Au), calcium (Ca), lithium (Li), chromium (Cr), and aluminum (Al), or an alloy thereof. The reflective layer and the semi-transmissive layer are determined based on a thickness, and the semi-transmissive layer may be formed to a thickness of 200 nm or less. As the thickness becomes small, the transmittance of light is increased. However, when the thickness is excessively small, resistance is increased.

The transparent layer may be formed of a material such as indium tin oxide (ITO), indium zinc oxide (IZO), zinc oxide (ZnO) or indium oxide (In₂O₃).

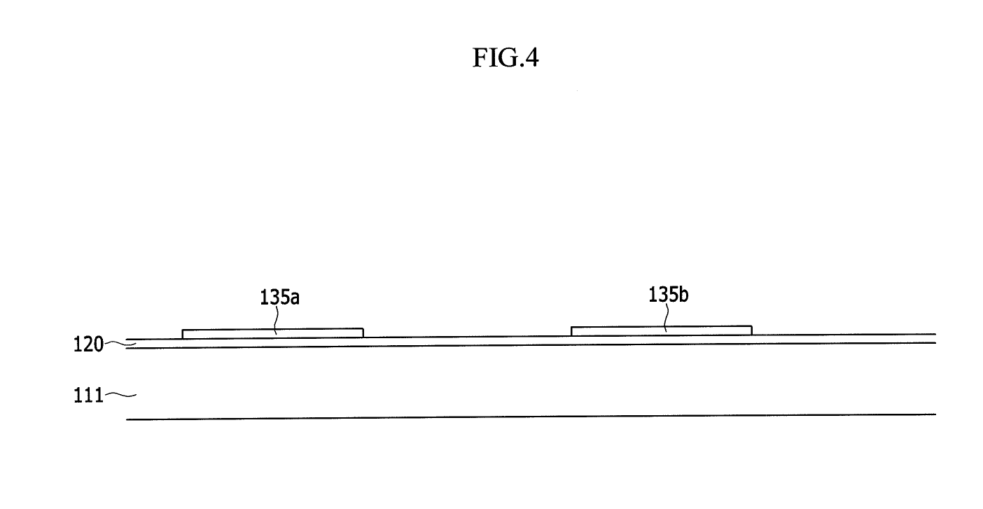

Hereinafter, a method of manufacturing the organic light emitting diode display will be described in detail with reference to FIGS. 4 to 10 together with aforementioned FIGS. 2 and 3.

FIGS. 4 to 10 are views illustrating a method of manufacturing the organic light emitting diode display according to an example embodiment according to a process order.

First, as illustrated in FIG. 4, the buffer layer 120 is formed on the substrate 111. The buffer layer 120 may be formed of silicon nitride or silicon oxide.

Further, the semiconductors 135a and 135b are formed by forming an amorphous silicon layer on the buffer layer 120, and crystallizing and then patterning the amorphous silicon layer.

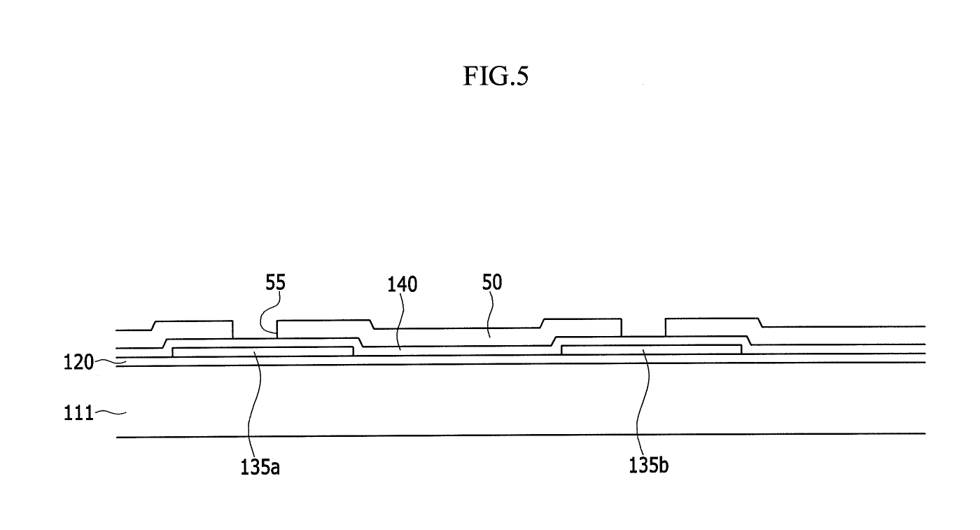

Next, as illustrated in FIG. 5, the gate insulating layer 140 and a sacrificial pattern 50 are formed on the semiconductors 135a and 135b.

The gate insulating layer 140 may be formed of silicon oxide or silicon nitride to a thickness of about 1,000 Å to about 1,300 Å. Further, the sacrificial layer may be formed of silicon nitride or tungsten to a thickness of about 3,500 Å to about 4,500 Å.

The sacrificial pattern 50 may be formed by patterning a sacrificial layer by a photolithography process, and includes an opening 55 which is the same as a wiring desired to be formed.

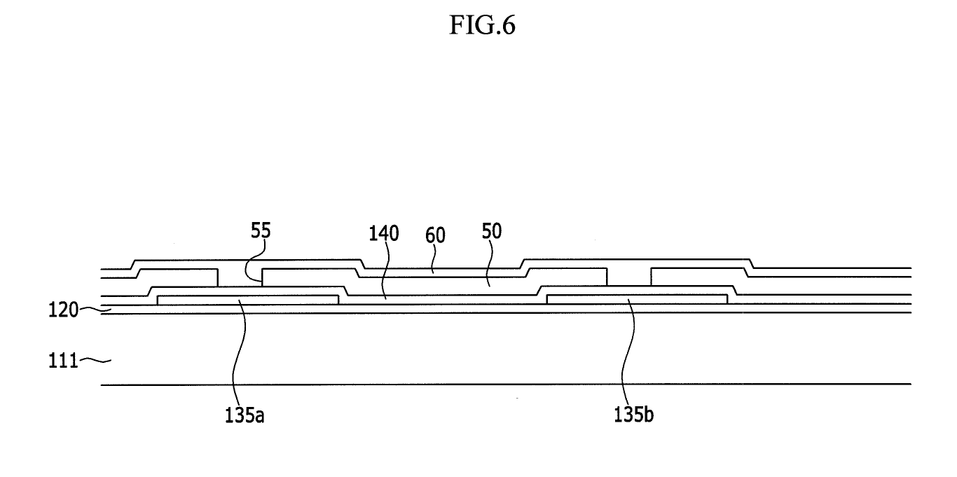

Next, as illustrated in FIG. 6, a copper layer 60 is formed so as to fill the opening 55. In this case, the copper layer may be formed to a thickness of about 3,000 Å to about 5,000 Å. The copper layer 60 may be formed by a method such as sputtering or plating.

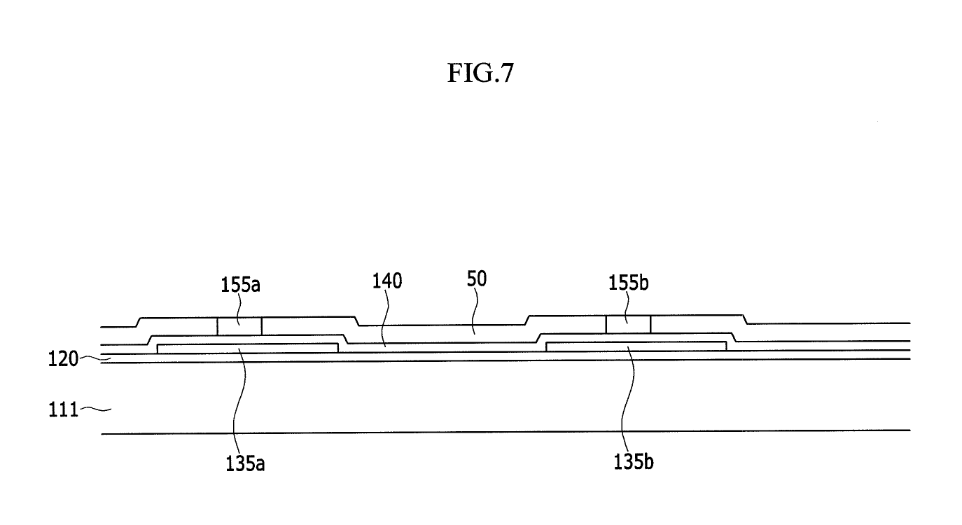

Next, as illustrated in FIG. 7, a gate line including the first gate electrode 155a and the second gate electrode 155b are formed by chemical mechanical polishing.

In this case, the polishing is continued until the sacrificial pattern 50 is exposed, and an upper portion of the sacrificial pattern 50 may be partially removed in order to sufficiently remove even the sacrificial pattern to be left on the electrode. Accordingly, the polishing may be performed until a thickness of about 1,000 Å to about 3,000 Å of the copper layer is left.

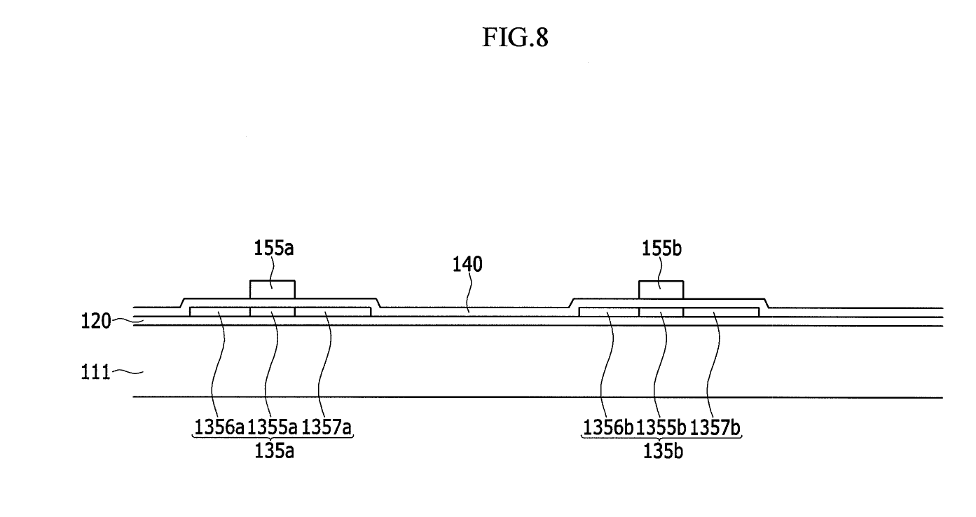

Next, as illustrated in FIG. 8, after the sacrificial pattern is removed, the source regions 1356a and 1356b and the drain regions 1357a and 1357b are formed by doping conductive impurity ions with a high concentration on the semiconductors 135a and 135b by using the gate line including the gate electrodes 155a and 155b as a mask. The spaces between the source regions 1356a and 1356b and the drain regions 1357a and 1357b serve as the channel regions 1355a and 1355b.

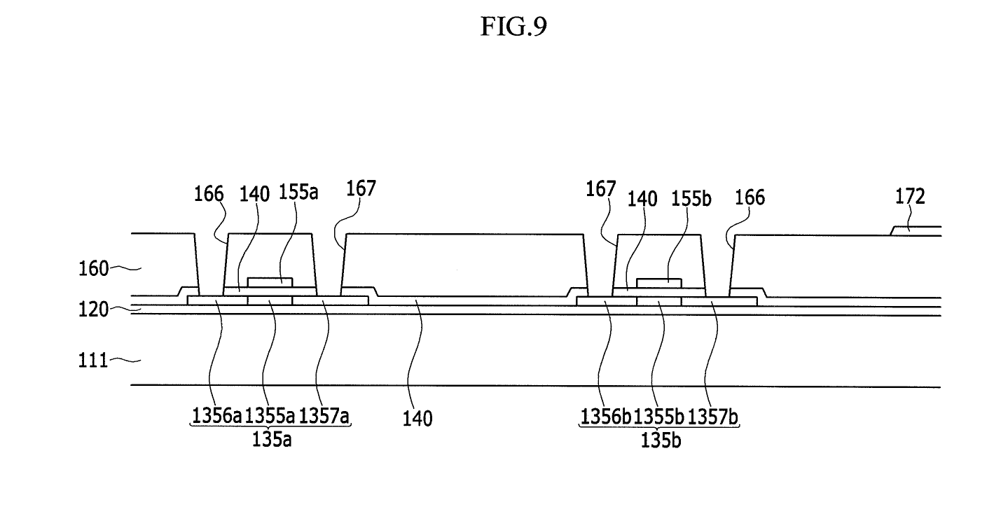

Next, as illustrated in FIG. 9, the first interlayer insulating layer 160 is formed on the gate electrodes 155a and 155b.

Next, the contact holes 166 and 167 through which the first semiconductor 135a and the second semiconductor 135b are exposed are formed by etching the first interlayer insulating layer 160 and the gate insulating layer 140, and a contact hole (not illustrated) through which the second gate electrode is exposed is formed by etching the first interlayer insulating layer 160.

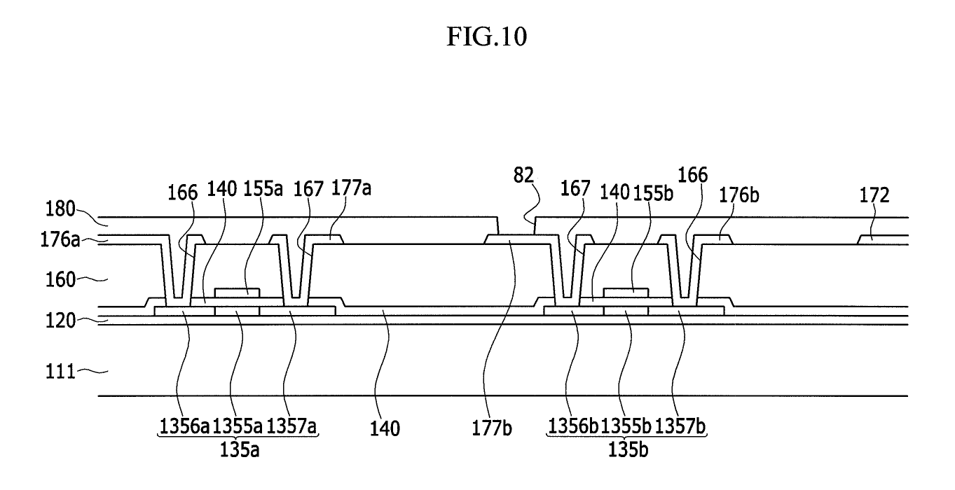

Next, as illustrated in FIG. 10, the data lines (not illustrated) including the first source electrode 176a, the driving voltage lines 172 including the second source electrode 176b, the first drain electrode 177a, and the second drain electrode 177b, which are connected to the source regions 1356a and 1356b and the drain regions 1357a and 1357b through the contact holes 166 and 167, respectively, are formed by forming a metal layer on the first interlayer insulating layer 160 and the patterning the metal layer.

Then, the second interlayer insulating layer 180 is formed on the data lines including the first source electrode 176a, the driving voltage lines 172 including the second source electrode 176b, the first drain electrode 177a, and the second drain electrode 177b.

Then, the contact hole 82 through which the second drain electrode 177b is exposed is formed by etching the second interlayer insulating layer 180.

Next, as illustrated in FIG. 3, the first electrode 710 is formed by forming a metal layer on the second interlayer insulating layer 180 and then patterning the metal layer.

Then, the pixel defining layer 190 including the opening 195 is formed on the first electrode 710, the organic emission layer 720 is formed inside the opening 195 of the pixel defining layer 190, and the second electrode 730 is formed on the organic emission layer 720.

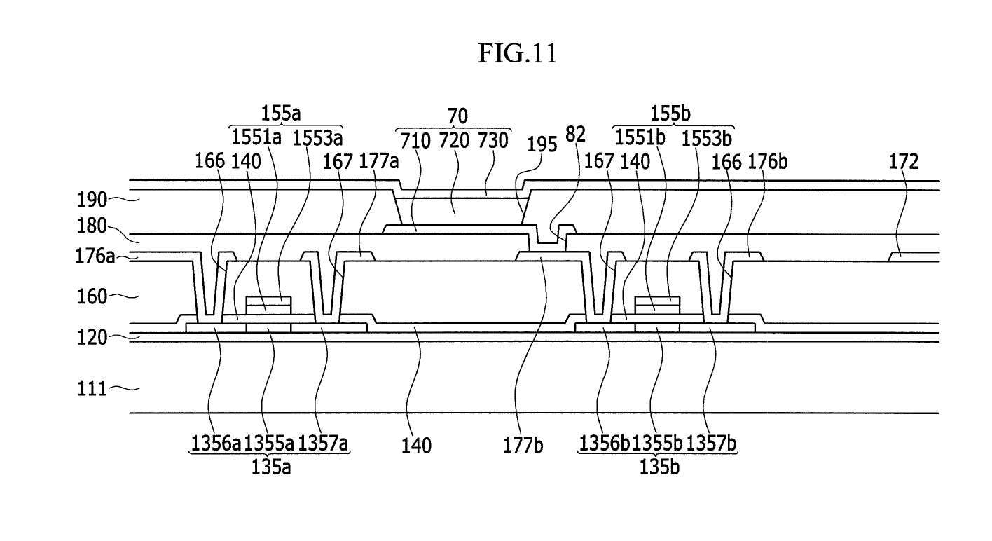

FIG. 11 is a cross-sectional view of an organic light emitting diode display according to another example embodiment, and is a cross-sectional view taken along line III-III of FIG. 2.

In the example embodiment illustrated in FIG. 11, the organic light emitting diode display according to the present example embodiment has mostly the same configuration as the interlayer configuration of FIG. 2, and thus parts that are different will be described in detail.

The first gate electrode 155a and the second gate electrode 155b of the organic light emitting diode display of FIG. 11 include lower layers 1551a, 1551b, and 158a, and upper layers 1553a, 1553b, and 158b.

The lower layers 1551a and 1551b are formed of tungsten (W), and upper layers 1553a and 1553b are formed of copper (Cu).

Since copper of the upper layer is not in direct contact with the gate insulating layer 140 under the upper layer, the lower layer prevents copper from being diffused to the gate insulating layer 140.

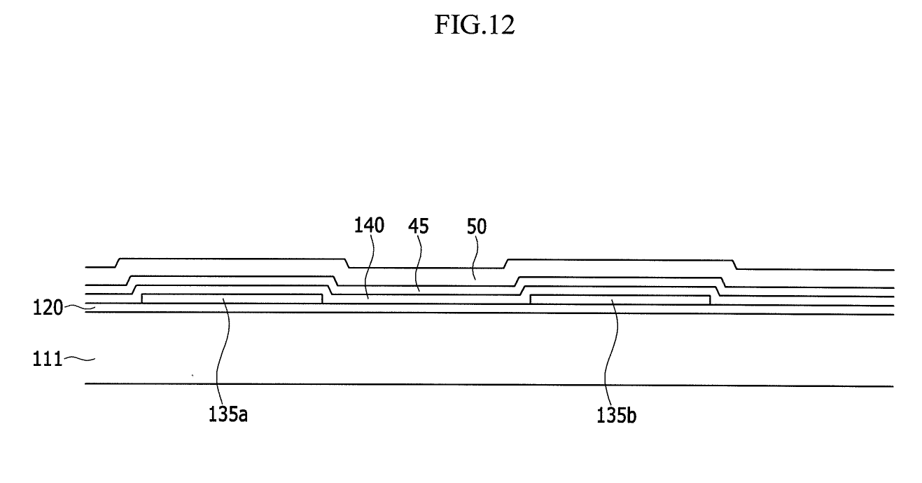

Hereinafter, a method of manufacturing the organic light emitting diode display of FIG. 11 will be described in detail with reference to FIGS. 12 to 15 together with aforementioned FIGS. 4, 9, and 10.

FIGS. 12 to 15 are cross-sectional views illustrating the method of manufacturing the organic light emitting diode display according to another example embodiment.

First, as illustrated in FIG. 4, the buffer layer 120 is formed on the substrate 111. The buffer layer 120 may be formed of silicon nitride or silicon oxide.

Further, the semiconductors 135a and 135b are formed by forming an amorphous silicon layer on the buffer layer 120, and crystallizing and then patterning the amorphous silicon layer.

Next, as illustrated in FIG. 12, the gate insulating layer 140 and an etch stop layer 45 are stacked on the semiconductors 135a and 135b, and the sacrificial pattern 50 is formed on the etch stop layer 60.

The gate insulating layer 140 may be formed of silicon oxide or silicon nitride to a thickness of about 1,000 Å to about 1,300 Å, and the etch stop layer 45 may be formed of tungsten to a thickness of about 100 Å to about 500 Å.

Further, the sacrificial pattern 50 may be formed of silicon nitride to a thickness of about 3,500 Å to about 4,500 Å, and then patterned by a photolithography process. In this case, the etching may be performed until the etch stop layer 45 is exposed.

As described above, when the etch stop layer 45 is formed, it is possible to prevent a surface of the gate insulating layer 140 from being damaged due to exposure of the gate insulating layer 140 to the etching process during the etching.

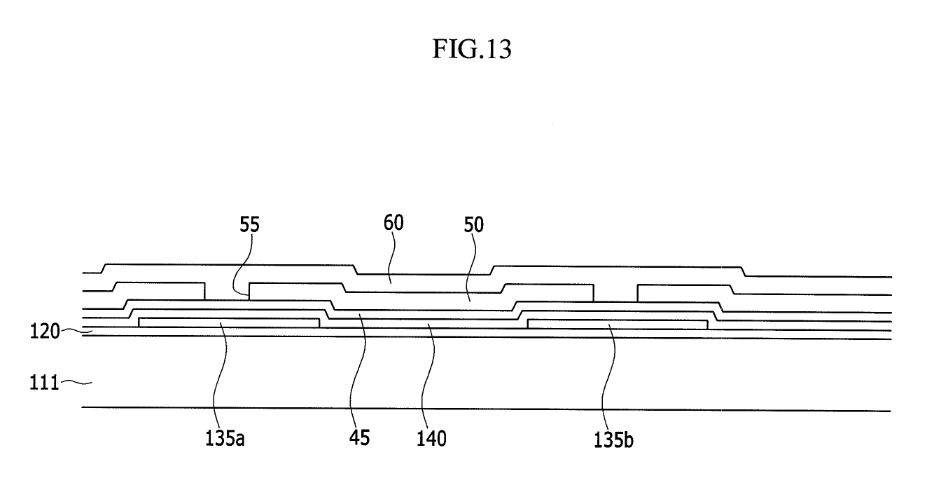

Next, as illustrated in FIG. 13, the copper layer 60 is formed so as to fill the opening 55. In this case, the copper layer may be formed to a thickness of about 3,000 Å to about 5,000 Å.

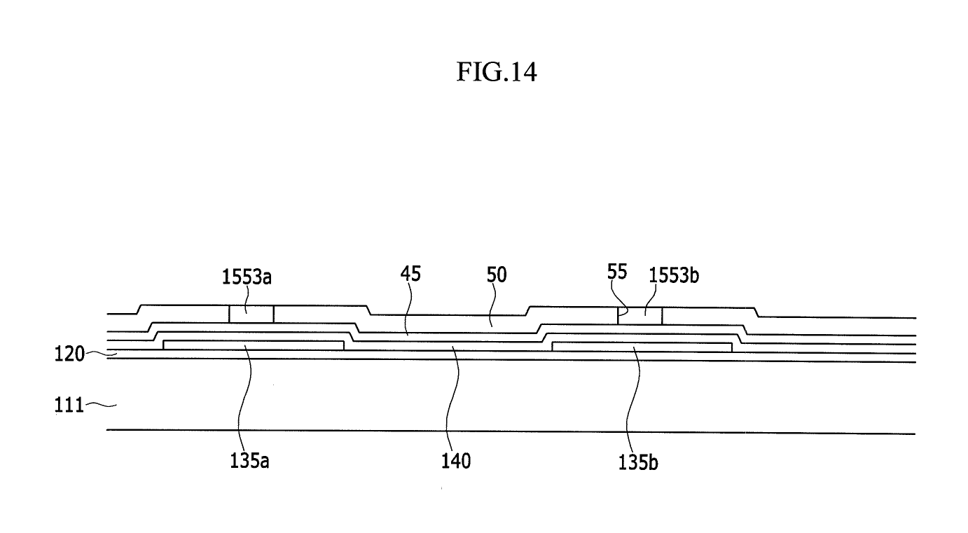

Next, as illustrated in FIG. 14, polishing is continued until the sacrificial pattern 50 is exposed by using chemical mechanical polishing.

After the polishing, the thickness of the copper layer may be about 1,000 Å to about 3,000 Å.

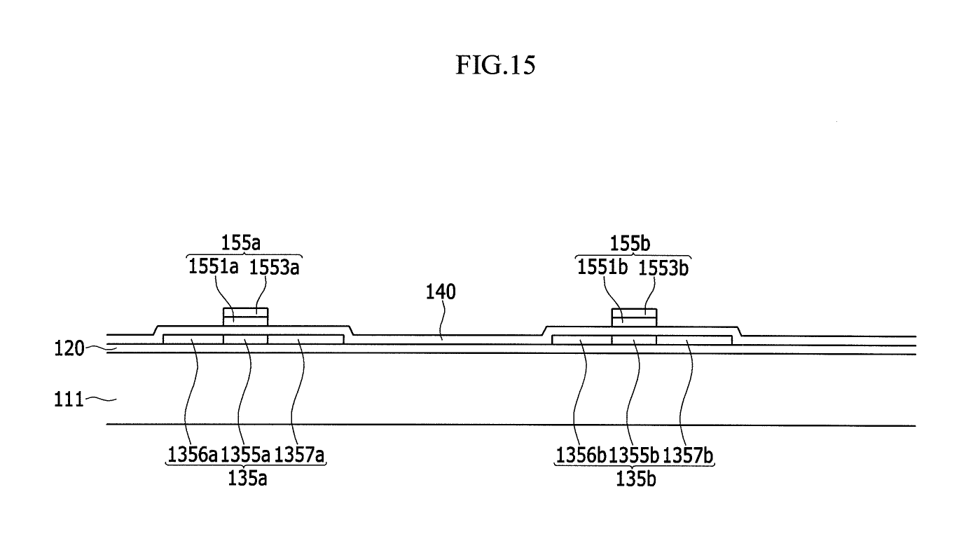

Next, as illustrated in FIG. 15, the gate lines including the first gate electrode 155a including the lower layers 1551a, 1551b, and 158a and the upper layers 1553a, 1553b, and 158b and the second gate electrode 155b are formed by removing the sacrificial pattern 50 and the etch stop layer 45 under the sacrificial pattern.

The sacrificial pattern 50 may be removed by phosphoric acid, and the etch stop layer 45 may be removed by hydrogen peroxide.

Then, as illustrated in FIG. 9, the first interlayer insulating layer 160 is formed on the gate electrodes 155a and 155b, and the contact holes 166 and 167 are formed.

Next, as illustrated in FIG. 10, the data lines 171 including the first source electrode 176a, the driving voltage lines 172 including the second source electrode 176b, the first drain electrode 177a, and the second drain electrode 177b, which are connected to the source regions 1356a and 1356b and the drain regions 1357a and 1357b through the contact holes 166 and 167, respectively, are formed on the first interlayer insulating layer 160.

Then, the second interlayer insulating layer 180 is formed on the data lines 171 including the first source electrode 176a, the driving voltage lines 172 including the second source electrode 176b, the first drain electrode 177a, and the second drain electrode 177b.

Then, the contact hole 82 through which the second drain electrode 177b is exposed is formed by etching the second interlayer insulating layer 180.

Next, as illustrated in FIG. 11, the first electrode 710 is formed by forming a metal layer on the second interlayer insulating layer 180 and then patterning the metal layer. Then, the pixel defining layer 190 including the opening 195 is formed on the first electrode 710, the organic emission layer 720 is formed inside the opening 195 of the pixel defining layer 190, and the second electrode 730 is formed on the organic emission layer 720.

By way of summation and review, a thin film transistor array panel may include a gate wiring for transmitting a scan signal and a data wiring for transmitting an image signal, and may include a thin film transistor connected with the gate wiring and the data wiring, a pixel electrode connected with the thin film transistor, and the like. A data voltage is transmitted through the data wiring to the pixel electrode according to a gate signal transmitted through the gate wiring. The thin film transistor includes a semiconductor layer on which a gate electrode (which is a part of the gate wiring) and a channel are formed, and a source electrode and a drain electrode (which are parts of the data wiring). In such a thin film transistor array panel, as a size of a substrate is increased, RC delay may be generated due to resistance and capacitance of the wiring. Thus, low resistance wiring may be used. Various metals, e.g., copper, may be used in order to form a wiring having low resistance.

As described above, embodiments may provide a method of manufacturing a thin film transistor array panel in which a wiring is formed of copper, a metal having low resistance. It may be possible to form a wiring having low resistance when the thin film transistor array panel is manufactured by a method according to an embodiment.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a thin film transistor array panel, the method comprising;
forming a semiconductor on a substrate;
forming a gate insulating layer on the semiconductor;
forming a sacrificial layer including an opening on the gate insulating layer;
forming a copper layer on the sacrificial layer, the copper layer filling the opening;
forming a gate wiring by polishing the copper layer by chemical mechanical polishing until the sacrificial layer is exposed;
removing the sacrificial layer;
forming a source region and a drain region by doping conductive impurities on the semiconductor by using the gate wiring as a mask;
forming a first interlayer insulating layer covering the gate wiring; and
forming a source electrode and a drain electrode connected to the source region and the drain region, respectively, on the first interlayer insulating layer.

2. The method as claimed in claim 1, wherein the sacrificial layer is formed of silicon nitride or tungsten.

3. The method as claimed in claim 1, wherein the sacrificial layer is formed to a thickness of about 3,500 Å to about 4,500 Å.

4. A method of manufacturing a thin film transistor array panel, the method comprising:
forming a semiconductor on a substrate;
forming a gate insulating layer on the semiconductor;
forming an etch stop layer on the gate insulating layer;
forming a sacrificial layer including an opening on the etch stop layer;
forming a copper layer on the sacrificial layer, the copper layer filling the opening;
forming an upper layer of a gate electrode by polishing the copper layer by chemical mechanical polishing until the sacrificial layer is exposed;
removing the sacrificial layer;
forming a lower layer of the gate electrode by removing the exposed etch stop layer;
forming a source region and a drain region by doping conductive impurities on the semiconductor by using the gate electrode as a mask;
forming a first interlayer insulating layer covering the upper and lower gate electrode layers; and
forming a source electrode and a drain electrode connected to the source region and the drain region, respectively, on the first interlayer insulating layer.

5. The method as claimed in claim 4, wherein the sacrificial layer is formed of silicon nitride.

6. The method as claimed in claim 5, wherein the sacrificial layer is formed to a thickness of about 3,500 Å to about 4,500 Å.

7. The method as claimed in claim 4, wherein the etch stop layer is formed of tungsten.

8. The method as claimed in claim 4, wherein the etch stop layer is formed to a thickness of about 100 Å to about 500 Å.
